(19) United States
(12) Patent Application Publication
(10) Pub. No.: US 2025/0079332 A1
(43) Pub. Date: Mar. 6, 2025

(54) Power converter package with shielding against common mode conducted emissions

(71) Applicant: Huawei Digital Power Technologies Co., Ltd., Shenzhen (CN)

(72) Inventors: Andreas Munding, Nuremberg (DE); Lasse Petteri Palm, Nuremberg (DE); Gilberto Curatola, Nuremberg (DE)

(73) Assignee: Huawei Digital Power Technologies Co., Ltd., Shenzhen (CN)

(21) Appl. No.: 18/952,995

(22) Filed: Nov. 19, 2024

Related U.S. Application Data
(63) Continuation of application No. PCT/EP2022/063498, filed on May 19, 2022.

(51) Int. Cl. H01L 23/552; H01L 23/498; H01L 23/538; H01L 25/065; H02M 7/00

(52) U.S. Cl. CPC H01L 23/552; H01L 23/5385; H01L 25/0655; H02M 7/003; H01L 23/49811

(57) ABSTRACT

The disclosure relates to a power converter package (100) for converting a first DC voltage and a second DC voltage into a common AC voltage. The power converter package comprises: a first power semiconductor (130) and a second power semiconductor (140); a first substrate (110); and a second substrate (120). The first substrate (110) comprises a first supply voltage area (113) being formed to supply the first DC voltage and a second supply voltage area (114) being formed to supply the second DC voltage. The first substrate (110) comprises a base metal area (115) being arranged on a first substrate lower main face (112). The base metal area (115) is configured to extract dissipated heat from the first power semiconductor (130) and the second power semiconductor (140). The second substrate (120) comprises an AC voltage output area (150) formed to provide the AC voltage.

### CROSS-REFERENCE TO RELATED APPLICATIONS

This application is a continuation of International Application No. PCT/EP2022/063498, filed on May 19, 2022, the disclosure of which is hereby incorporated by reference in its entirety.

### TECHNICAL FIELD

The disclosure relates to the field of module packaging and assemblies, in particular chip embedding based, PCB based or ceramic substrate based packaging like DBC, AMB, etc. The disclosure further relates to fast switching power devices packaging, for example as required to make use of the benefits of wide bandgap (WBG) semiconductors such as SiC or GaN. The frequencies can range from 50 kHz up to several MHz, where the switching frequency can cause EMI issues. In particular, the disclosure relates to a power converter package with shielding against common mode conducted emissions and a multi-phase system comprising multiple of such power converter packages. Specifically, the disclosure relates to a structure and method to internally isolate and shield a power module against common mode conducted electromagnetic emissions.

### BACKGROUND

Power converters typically consist of power modules, which consist of two or more power semiconductors, two or more DC voltage supply terminals (+=HS, high side; and −=LS, low side), one or more AC (alternating current) voltage terminals, several control & sense terminals, and a metallic thermal interface (heatsink). For operating voltages higher than 100V the metallic thermal interface area is typically connected to GND (ground) potential, whereas the DC (direct current) voltage terminals are isolated from GND potential or, in some systems, DC-, that is, low side, or lower voltage potential, can be equal to GND potential. During operation, an AC voltage is created at the AC voltage terminal, which swings between the positive and negative DC voltage levels.

In power modules used for power conversion, common mode (CM) conducted electromagnetic emission (EMI) can exceed the permitted levels given by national or international standards or by specification requirements. At switching frequencies in the range of hundreds of kHz up to MHz range the capacitive or inductive coupling effect becomes severe as the change rate of voltage dV/dt and respectively the change rate of current dI/dt reaches levels which induce considerable levels of current/voltage into nearby conductor structures.

These coupling effects require measures to either compensate the unwanted EMI coupling effects by bulky filters. Filters can counteract or even cancel out all benefits from usage of fast switching capable wide bandgap semiconductors.

Thus, it is worth to spend much effort into avoiding of the capacitive/inductive coupling effects by special design/structuring of the power module.

### SUMMARY

This disclosure provides a solution to overcome the above-described EMI problems. In particular, new capacitive shielding techniques inside a power module assembly are disclosed to reduce CM conducted EMI.

The foregoing and other objects and other objectives are achieved by the features of the independent claims. Further implementation forms are apparent from the dependent claims, the description and the figures.

This disclosure presents embodiments to implement new capacitive shielding techniques inside a power module assembly or power converter package. The various embodiments presented in this disclosure can be classified into the following two types:
a) Embodiments 1, 2 & 6 constitute entirely new arrangements, which provide a technical benefit over existing power converter arrangements. This is possible by complexity reduction, increase of degrees of freedom for cost efficient material choice, and improvement of thermal management.
b) Embodiments 3, 4 & 5 combine power converter arrangements in a new way which allows to employ the EMI shielding technique to a larger variety of different types of power semiconductors.

The disclosure presents a solution for providing integrated capacitive EMI shielding against common mode conducted emission (CM EMI) of the AC voltage areas inside a power module. EMI shielding is effectively provided in a better way with less effort and cost than in currently available power modules, in particular for semiconductor devices with vertical current flow.

The solution is based on an investigation of possibilities to integrate isolation and shielding to power modules. The solution presented in this disclosure covers the open gap between currently available solutions and feasible variations projected to future power modules, extended to include wide band gap semiconductors.

A key concept is the use of a substrate, that exists between the alternating voltage output area and supply voltage area, for isolation and shielding. The various embodiments presented in this disclosure describe how shielding can be implemented in various kinds by arranging the power semiconductors, the substrates and the conductor structures relative to each other and connect them to a half-bridge topology as one example.

The following features may be implemented in Embodiments 1, 2 and 6 described below in more detail, for example:
1) One or several dies are mounted on a base substrate that has conductive layer at least on one side;
2) The input terminals of the HS and LS dies are connected to this layer;
3) An additional substrate is mounted on top of the substrate next to the power dies;
4) The output terminal of both dies are connected to this additional substrate;
5) The alternating voltage output of the assembly is located on top of the additional substrate and it is isolated and shielded from the base substrate.

The following features may be implemented in Embodiments 3 to 5 described below in more detail, for example:
1) Solution for lateral current flow devices, which is not covered by existing solutions;
2) One or several dies are mounted on a substrate that has a conductive layer at least on one side;
3) The input terminals of the HS and LS dies are connected to this layer;
4) An additional substrate is mounted on top of the substrate next to the power dies;
5) The AC output terminal and either the HS semiconductor or the LS semiconductor are located on the additional substrate;
6) The output terminals of both dies are connected to the additional substrate;
7) The additional substrate is used to isolate and shield the alternating voltage output area from the supply voltage area.

In order to describe the disclosure in detail, the following terms, abbreviations and notations will be used:
DC direct current
AC alternating current
HS high side
LS low side
GND ground
CM common mode
EMI electromagnetic emission
DBC direct bonded copper
AMB active metal brazed
WBG wide bandgap
SiC Silicon Carbide
GaN Gallium Nitride

The solution presented in this disclosure may be applied to power semiconductors with vertical current flow, referred to as vertical devices hereinafter, and also to power semiconductors with lateral current flow, referred to as lateral devices hereinafter.

In power semiconductors with vertical current flow, a vertical current flows through the backside of the semiconductor chip. Typically, both HS (high-side, positive supply voltage area, DC+) and LS semiconductors are in face-up orientation, where the face-up side is the front side of a semiconductor, i.e., the face on which most of the semiconductor manufacturing processes are carried out. This face usually constitutes the terminals for clips or wirebond interconnections.

Power semiconductors with vertical current flow can be IGBTs (insulated gate bipolar transistors) and FRDs (freewheeling diodes), for example, or SiC based MOSFETs. However, GaN based semiconductors and many Si based MOSFETS are semiconductors with a lateral current flow by principle (lateral devices). That is, the switched current enters and leaves on the front side of the semiconductor.

According to a first aspect, the disclosure relates to a power converter package for converting a first DC voltage and a second DC voltage into a common AC voltage, the power converter package comprising: a first power semiconductor and a second power semiconductor which are configured to generate the common AC voltage based on switching between the first DC voltage and the second DC voltage; a first substrate having a first substrate upper main face and a first substrate lower main face opposing the first substrate upper main face, the first substrate comprising a first supply voltage area being formed to supply the first DC voltage and a second supply voltage area being formed to supply the second DC voltage, the first supply voltage area and the second supply voltage area being arranged on the first substrate upper main face; wherein the first substrate comprises a base metal area being arranged on the first substrate lower main face, the base metal area being configured to extract dissipated heat from the first power semiconductor and the second power semiconductor; the first power semiconductor having a first semiconductor upper main face and a first semiconductor lower main face opposing the first semiconductor upper main face, the first power semiconductor comprising an input terminal and an output terminal, wherein the input terminal of the first power semiconductor is connected to the first supply voltage area; the second power semiconductor having a second semiconductor upper main face and a second semiconductor lower main face opposing the second semiconductor upper main face, the second power semiconductor comprising an input terminal and an output terminal, wherein the input terminal of the second power semiconductor is electrically coupled to the second supply voltage area; and a second substrate having a second substrate upper main face and a second substrate lower main face opposing the second substrate upper main face, the second substrate comprising an AC voltage output area formed to provide the AC voltage, the AC voltage output area being placed on top of the second substrate upper main face, wherein the AC voltage output area is electrically coupled to the output terminal of the first power semiconductor and the output terminal of the second power semiconductor, wherein the second substrate lower main face is placed on top of the second supply voltage area, wherein the second supply voltage area is configured to isolate and shield the AC voltage output area against the base metal area by a placement of the second supply voltage area between the AC voltage output area and the base metal area.

Such a power converter package provides integrated capacitive EMI shielding against common mode conducted emission of the AC voltage areas inside the package.

Due to the shielding, the effects of forming of a capacitor by the AC output area and the base metal area which would couple high frequency noise into the base metal area, can be significantly reduced. Thus, fast switching power semiconductor devices like for example GaN devices or SiC devices can be efficiently implemented in a converter.

In an exemplary implementation of the power converter package, the second supply voltage area is arranged at least partly below the second semiconductor lower main face and extends underneath the AC voltage output area.

This overlap of the second supply voltage area with the AC voltage output area creates the shielding function, thereby reducing common mode EMI.

In the following, exemplary implementations of the power converter package are described which correspond to different embodiments. All exemplary implementations describe arrangements for lateral devices-except the sixth embodiment.

In an exemplary implementation of the power converter package corresponding to a first embodiment, the first power semiconductor and the second power semiconductor are lateral devices, the input terminal of the first power semiconductor being arranged on the first semiconductor upper main face and the input terminal of the second power semiconductor being arranged on the second semiconductor upper main face.

Implementation of the shielding can be advantageously implemented for such lateral devices. The second substrate can be arranged next to the first power semiconductor and next to the second power semiconductor. This is the reason why the second substrate area is reduced in area and why it does not have a heat generating device on top. Due to this reduced area, the second substrate can have lower requirement with respect to thermal performance.

In an exemplary implementation of the power converter package corresponding to the first embodiment, the first power semiconductor and the second power semiconductor are face-up mounted on the first substrate, the first semiconductor lower main face facing the first supply voltage area and the second semiconductor lower main face facing the second supply voltage area.

In such a power converter package, the shielding can be advantageously implemented by using cost efficient materials for the second substrate, because no significant heat is generated on it or needs to be conducted away from it.

In an exemplary implementation of the power converter package corresponding to the first embodiment, the first supply voltage area extends at least partly underneath the first semiconductor lower main face.

Such a structure provides the advantage that the thermal path underneath the second power semiconductor is optimized, and the shielding substrate, i.e., the second substrate, does not require high thermal performance materials.

In an exemplary implementation of the power converter package corresponding to a second embodiment, both, the first power semiconductor and the second power semiconductor are lateral devices and are face-up mounted on the first substrate, the first semiconductor lower main face and the second semiconductor lower main face facing the second supply voltage area.

For such a power converter package, the same advantages apply as described for the first embodiment. The shielding can be advantageously implemented by using cost efficient materials for the second substrate, because no significant heat is generated on it or needs to be conducted away from it.

In an exemplary implementation of the power converter package corresponding to the second embodiment, the second supply voltage area extends at least partly underneath the first semiconductor lower main face, at least partly underneath the second semiconductor lower main face and extends underneath the AC voltage output area.

For such a power converter package, the same advantages apply as described for the first embodiment. The thermal path underneath the second power semiconductor is optimized, and the shielding substrate, i.e., the second substrate, does not require high thermal performance materials.

In an exemplary implementation of the power converter package corresponding to the second embodiment, the first supply voltage area is placed next to the first power semiconductor.

This provides the advantage, as for all other embodiments described in this disclosure, of a compact design of the power converter package.

In an exemplary implementation of the power converter package corresponding to a third embodiment, the first power semiconductor and the second power semiconductor are flip-chip mounted on the second substrate, the first semiconductor upper main face and the second semiconductor upper main face facing the first substrate upper main face.

Provided the first and the second substrate are good heat conductors, the flip-chip arrangement provides the advantage that heat can be better extracted from lateral devices, because the heat does not have to be conducted from the upper main faces of the power semiconductors to the lower main faces. Instead it can be directly extracted through the second substrate and the first substrate to the heatsink.

The power semiconductor backside (the lower main face) can be electrically connected or not. This can offer optimization possibilities for some applications.

In an exemplary implementation of the power converter package corresponding to the third embodiment, the second supply voltage area extends at least partly underneath the first semiconductor upper main face, at least partly underneath the second semiconductor upper main face and extends underneath the AC voltage output area.

For such a power converter package, the same advantages apply as described for the first embodiment. The thermal path underneath the second power semiconductor is optimized.

In an exemplary implementation of the power converter package corresponding to the third embodiment, the first supply voltage area is placed next to the first power semiconductor.

As for all other embodiments described in this disclosure, this provides the advantage of a compact design of the power converter package.

In an exemplary implementation of the power converter package corresponding to a fourth embodiment, the first power semiconductor is face-up mounted on the first substrate and the second power semiconductor is face-up mounted on the second substrate, the first semiconductor lower main face facing the first supply voltage area and the second substrate lower main face facing the second supply voltage area.

For such a power converter package, an optimal shielding against common mode EMI can be achieved because the AC voltage area has maximum overlap with the second supply voltage area (DC supply area).

In an exemplary implementation of the power converter package corresponding to the fourth embodiment, the first supply voltage area extends at least partly underneath the first semiconductor lower main face.

For such a power converter package, the thermal path underneath the first power semiconductor is optimized, because there is no additional substrate necessary.

In an exemplary implementation of the power converter package corresponding to the fifth embodiment, the first power semiconductor is face-up mounted on the first substrate and the second power semiconductor is flip-chip mounted on the second substrate, the first semiconductor lower main face facing the first supply voltage area and the second semiconductor upper main face facing the second substrate upper main face.

For such a power converter package, the alternating voltage output area can be reduced to a fraction of the second substrate. Besides, the second power semiconductor backside (the lower main face) can be electrically connected or not. This can offer optimization possibilities for some applications.

In an exemplary implementation of the power converter package corresponding to the fifth embodiment, the second supply voltage area extends at least partly underneath the second semiconductor upper main face and the AC voltage output area.

Provided the first and the second substrate are good heat conductors, the flip-chip arrangement of the second power semiconductor provides the advantage that heat can be better extracted from lateral devices, because the heat does not have to be conducted from the upper main faces of the power semiconductors to the lower main faces. Instead it can be directly extracted through the second substrate and the first substrate to the heatsink.

In an exemplary implementation of the power converter package corresponding to the fifth embodiment, the first supply voltage area extends at least partly underneath the first semiconductor lower main face.

This is a characteristic for such a power converter package according to the fifth embodiment.

In an exemplary implementation of the power converter package corresponding to a sixth embodiment, the first power semiconductor and the second power semiconductor are vertical devices; the input terminal and the output terminal of the first power semiconductor being arranged on opposite first semiconductor main faces; and the input terminal and the output terminal of the second power semiconductor being arranged on opposite second semiconductor main faces.

For such a power converter package, the same advantages apply as described for the first embodiment.

In an exemplary implementation of the power converter package corresponding to the sixth embodiment, the first power semiconductor and the second power semiconductor are face-up mounted on the first substrate, the first semiconductor lower main face facing the first supply voltage area and the second semiconductor lower main face facing the second supply voltage area.

For such a power converter package, the same advantages apply as described for the first embodiment.

The second supply voltage area may extend at least partly underneath the second semiconductor lower main face and may extend at least partly underneath the second substrate lower main face.

In an exemplary implementation of the power converter package corresponding to the sixth embodiment, the first supply voltage area extends at least partly underneath the first semiconductor lower main face.

This results in an arrangement were the AC voltage area is reduced to a minimum.

The shielding can be advantageously implemented by using cost efficient materials for the second substrate, because no significant heat is generated on it or needs to be conducted away from it.

In an exemplary implementation of the power converter package, the first power semiconductor and the second power semiconductor are electrically connected to a half-bridge topology.

This provides the advantage that the power converter package can be advantageously applied in automotive and industrial application where half-bridges are required. In such applications, thermal performance can be improved by using the power converter package and EMI can be reduced at the same time.

In an alternative embodiment to embodiments 1, 2 or 6, the second substrate can be made of less thermally conductive material because no heat extraction through this substrate is required. This provides a cost advantage to EMI shielded modules.

In another embodiment first substrate and second substrate can be layers of a multi-layer ceramic substrate.

In another embodiment first substrate and second substrate can be metallized quartz, ceramic, or alumina filled organic compound material (=PCB laminate material or epoxy mold compound material in a narrower definition).

In an exemplary implementation of the power converter package, the AC voltage comprises a plurality of phases; wherein the AC voltage output area formed on the second substrate comprises a plurality of isolated phase sections, each phase section associated to a respective phase of the AC voltage; wherein the first substrate comprises a plurality of first supply voltage areas, each first supply voltage area associated with a respective phase of the AC voltage, wherein the first supply voltage areas are electrically connected to each other;
wherein the second substrate comprises a plurality of second supply voltage areas, each second supply voltage area associated with a respective phase of the AC voltage, wherein the second supply voltage areas are electrically connected to each other; and wherein the first substrate comprises a plurality of base metal areas, each base metal area associated with a respective phase of the AC voltage, wherein the base metal areas form a common base metal area.

In such a multiphase module in one package, first substrate and second substrate may be shared between multiple phases. That means that 1^{st} supply voltage areas of all phases fuse together, 2^{nd} supply voltage areas of all phases fuse together, and the base metal area of all phases fuse into one common base metal area. The second substrate of each module may be connected mechanically. It may have a lower main face electrical conductor area which connects or not between the multiple phases. The term “fuse” in a wider sense can have the meaning of only “electrically connected to each other (not mechanically)”. Then it can be multiple separate modules which function like a 3-phase system.

According to a second aspect, the disclosure relates to a multi-phase system, comprising: a plurality of power converter packages according to the first aspect, wherein the first supply voltage areas of the first substrates of the plurality of power converter packages are electrically connected to each other to form a common first supply voltage area for all phases of the multi-phase system; and wherein the second supply voltage areas of the first substrates of the plurality of power converter packages are electrically connected to each other to form a common second supply voltage area for all phases of the multi-phase system.

### BRIEF DESCRIPTION OF THE DRAWINGS

Further embodiments of the disclosure will be described with respect to the following figures, in which:

FIG. 1 shows a schematic cross section of a power converter package 100 according to a first embodiment;

FIG. 2 shows a schematic cross section of a power converter package 200 according to a second embodiment;

FIG. 3 shows a schematic cross section of a power converter package 300 according to a third embodiment;

FIG. 4 shows a schematic cross section of a power converter package 400 according to a fourth embodiment;

FIG. 5 shows a schematic cross section of a power converter package 500 according to a fifth embodiment;

FIG. 6 shows a schematic cross section of a power converter package 600 according to a sixth embodiment;

FIG. 7a shows a schematic cross section of the power converter package 100 according to the first embodiment shown in FIG. 1;

FIG. 7b shows a schematic top view of the power converter package 100 according to the first embodiment shown in FIG. 1;

FIG. 8 shows a schematic top view of a multi-phase system with shared supply voltage areas 800 according to a further embodiment; and

FIG. 9 shows a schematic top view of a multi-phase system 900 implemented by multiple of the power converter packages 100 shown in FIG. 1.

### DETAILED DESCRIPTION OF EMBODIMENTS

In the following detailed description, reference is made to the accompanying drawings, which form a part thereof, and in which is shown by way of illustration specific aspects in which the disclosure may be practiced. It is understood that other aspects may be utilized and structural or logical changes may be made without departing from the scope of the disclosure. The following detailed description, therefore, is not to be taken in a limiting sense, and the scope of the disclosure is defined by the appended claims.

It is understood that comments made in connection with a described method may also hold true for a corresponding device or system configured to perform the method and vice versa. For example, if a specific method step is described, a corresponding device may include a unit to perform the described method step, even if such unit is not explicitly described or illustrated in the figures. Further, it is understood that the features of the various exemplary aspects described herein may be combined with each other, unless specifically noted otherwise.

In the following Figures, different embodiments of a power converter package are shown.

All embodiments described below provide integrated capacitive EMI shielding against common mode conducted emission (CM EMI) of the AC voltage areas inside a power module.

Embodiments 1, 2 and 6 describe the implementation of shielding by usage of an additional substrate with minimized area and lower requirements with respect to thermal performance. This is achieved by use of power semiconductors with lateral current flow. In that case, large area backside contacts with alternating voltage can be eliminated. This allows convenient definition of oscillating conductor areas (AC voltage areas) to make these areas as small as possible. The smaller these areas, the less shielding is required. In the embodiments, the additional substrate is only used as connection point for the alternating voltage output contact. This allows usage of cost-efficient materials for this substrate, because no significant heat is generated on it or needs to be conducted away from it.

A solution for semiconductor devices with lateral current flow, such as e.g. GaN semiconductor devices is presented by embodiments 3, 4, 5 as described below.

The solution presented in this disclosure exploits the higher degrees of freedom in terms of backside contact that semiconductor devices with lateral current flow provide. The potential of this area can be freely defined in such a way, that the complete semiconductor backside area does not oscillate and therefore does not need to be shielded. In a half-bridge configuration this would be the case for the HS switch: Typically, the HS source potential can be connected to the GaN substrate potential at the die backside. Instead, for better shielding, the HS drain potential is connected to the substrate, as presented in this disclosure.

By selecting the LS supply voltage for the LS device backside, and HS supply voltage for HS device backside, the supply voltage areas extend over the die area and thus provide shielding for the on-die top-side AC terminals of the lateral current flow semiconductor device.

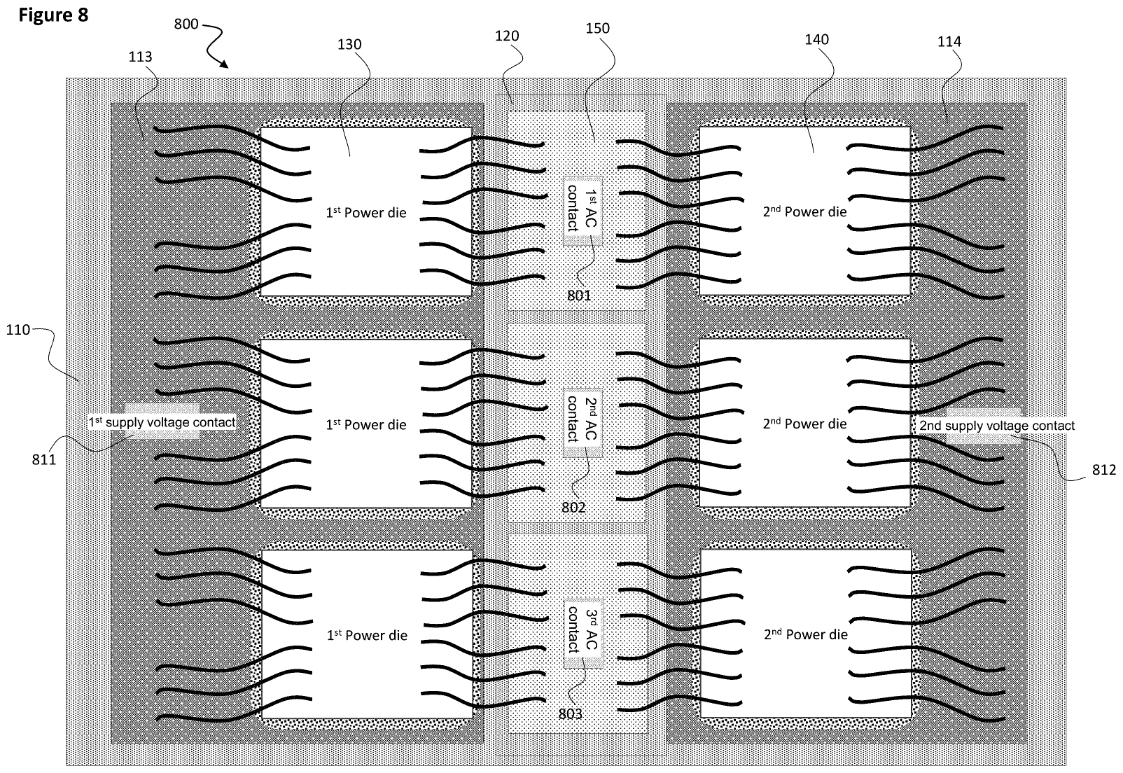

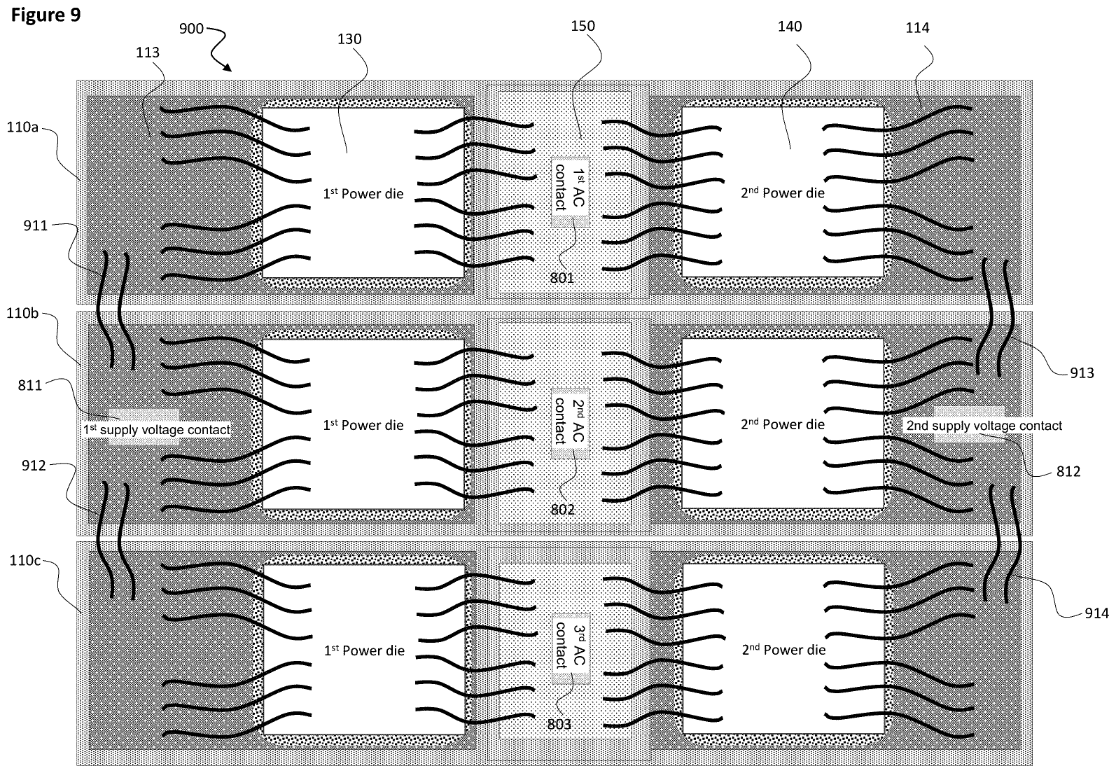

Table 1 provides an overview of the embodiments described below. There are six embodiments shown, preferred embodiment may be embodiment 1 for lateral devices and embodiment 6 for vertical devices. The embodiments are described in detail in the following, where the half-bridge topology only represents one example, which can be applied to multi-phase and multi-level power module topologies with more than one parallel dies or dies and diodes per switch position. Examples of multi-phase topologies are shown in FIGS. 8 and 9.

TABLE 1
Overview of exemplary embodiments presented in this disclosure.

| | Emb. 1 | Emb. 2 | Emb. 6 | Emb. 3 | Emb. 4 | Emb. 5 |
|---|---|---|---|---|---|---|
| HS die | S up | S up | S up | S down | S up | S up |
| orientation | | | | | | |
| LS die | S up | S up | S down | S down | S up | S down |
| orientation | | | | | | |
| Current flow | Lateral | lateral | vertical | lateral | lateral | Lateral |
| through dies | | | | | | |
| HS die | DC+ | DC− | DC+ | * | DC+ | DC+ |
| backside | | | | | | |
| potential | | | | | | |
| LS die | DC− | DC− | AC | * | AC | * |
| backside | | | | | | |
| potential | | | | | | |
| Die on | no | no | no | yes | yes | yes |
| additional | | | | | | |
| substrate | | | | | | |

All embodiments have following common properties:
1. The first power semiconductor input terminal is connected to the first supply voltage area;
2. The second power semiconductor input terminal is connected to the second supply voltage area.
3. The output terminal of the first and the second power semiconductor is connected to the alternating voltage output of the assembly.
4. The alternating voltage output area is arranged on an additional substrate which comprises a conductor structure at a surface of the substrate which is connected to the output terminals of the first and the second power semiconductor, wherein the substrate is arranged on top of the second supply voltage area.

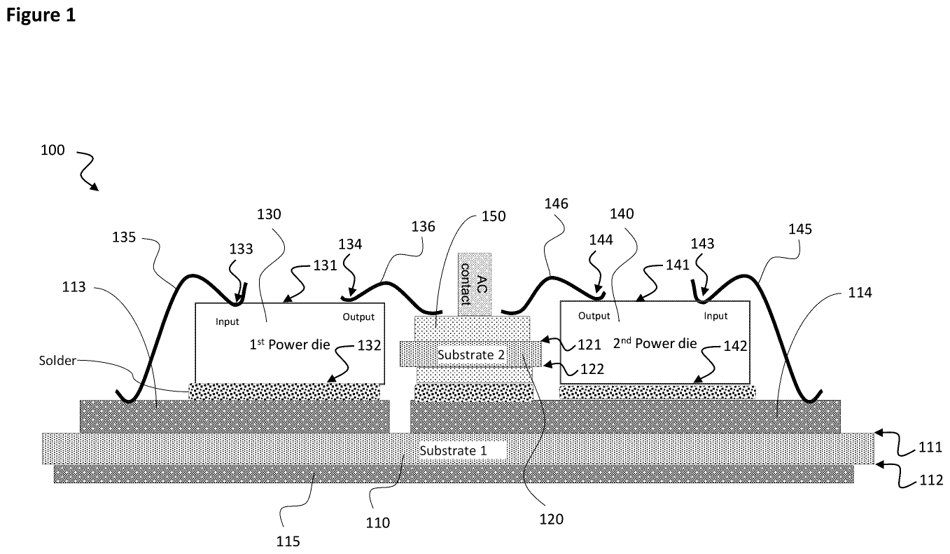

In Embodiment 1, HS and LS dies are face up, lateral current flow (see FIG. 1):
First and second power semiconductors are lateral devices.
First supply voltage area extends at least partly underneath the first power semiconductor facing the substrate side of the first power semiconductor.
Second supply voltage area extends at least partly underneath the second power semiconductor and the AC output of the assembly facing the substrate side of the second power semiconductor.

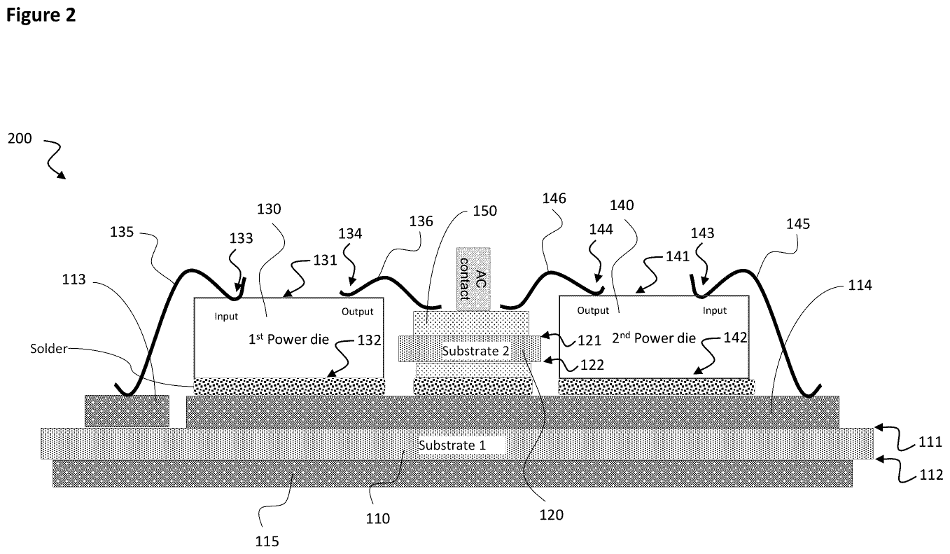

In Embodiment 2, HS and LS dies face up, lateral current flow, HS and LS backside on DC-(see FIG. 2):
First and second power semiconductors are lateral devices.
First supply voltage area is located next to the first power semiconductor.
Second supply voltage area extends at least partly underneath the first and second power semiconductor and the AC output of the assembly facing the substrate side of the second power semiconductor.

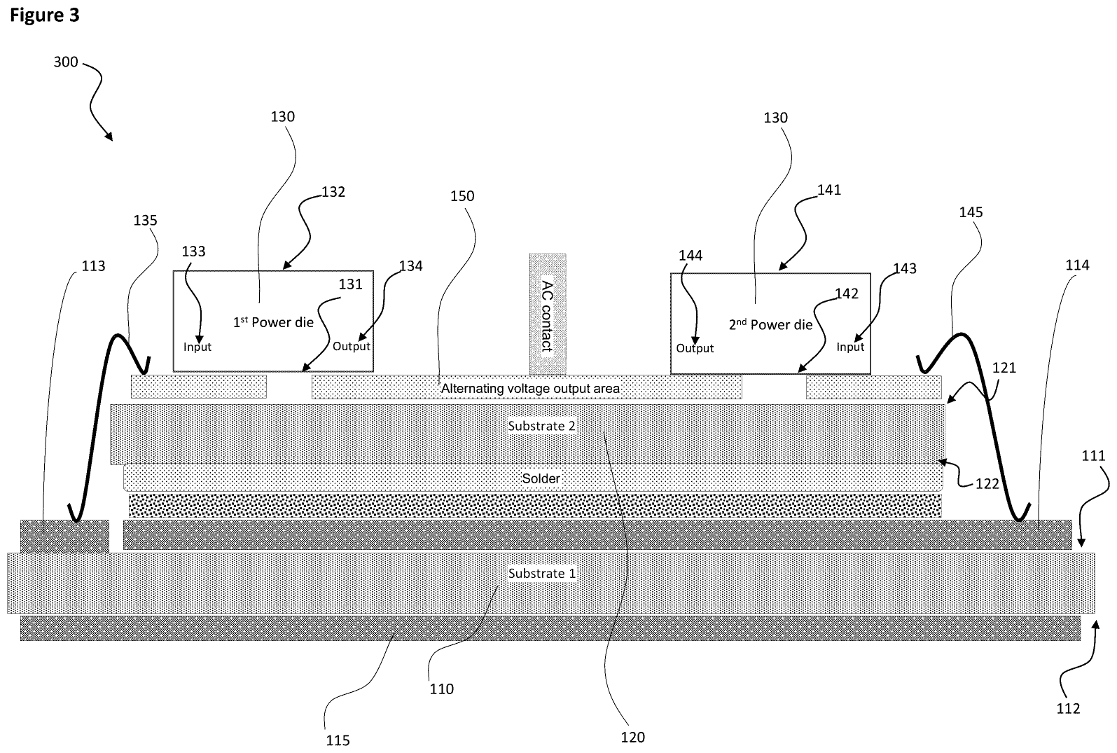

In Embodiment 3, HS and LS dies flip-chip/face down, lateral current flow, HS and LS backside for heatsink attach (see FIG. 3):
First and second power semiconductors are lateral devices.
First supply voltage area extends shortly before the boundary of the second power supply area.
Second supply voltage area extends at least partly underneath the first and the second power semiconductor and the AC output of the assembly facing the terminals of the power semiconductors.

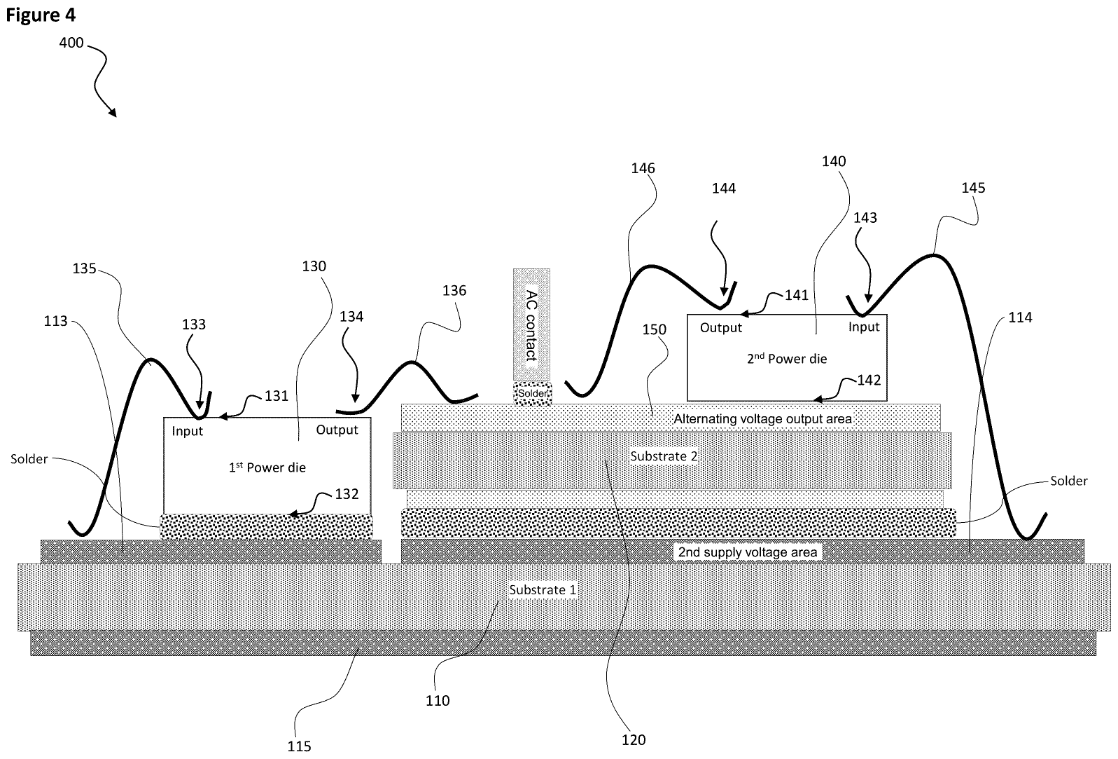

In Embodiment 4, HS and LS dies face up, lateral current flow, ≥1 die on additional substrate (see FIG. 4):
First and second power semiconductors are lateral devices.
First supply voltage area extends at least partly underneath the first power semiconductor facing the substrate side of the first power semiconductor.
Second supply voltage area extends at least partly underneath the second power semiconductor and the AC output of the assembly facing the substrate side of the second power semiconductor.

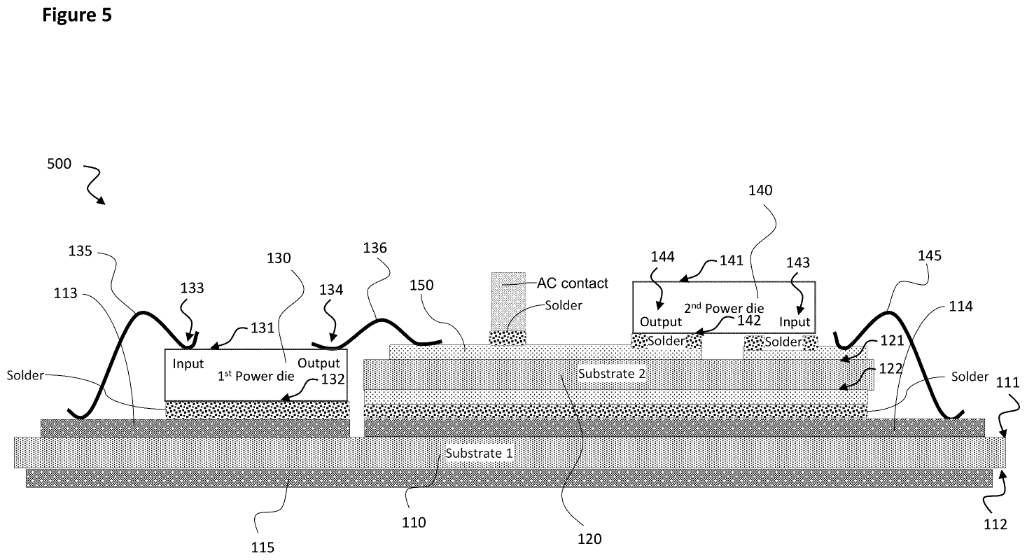

In Embodiment 5, HS face up, LS face-down, lateral current flow, ≥1 die on additional substrate (see FIG. 5):
First and second power semiconductors are lateral devices.
First supply voltage area extends at least partly underneath the first power semiconductor facing the substrate side of the first power semiconductor.
Second supply voltage area extends at least partly underneath the second power semiconductor and the AC output of the assembly facing the terminals of the second power semiconductor.

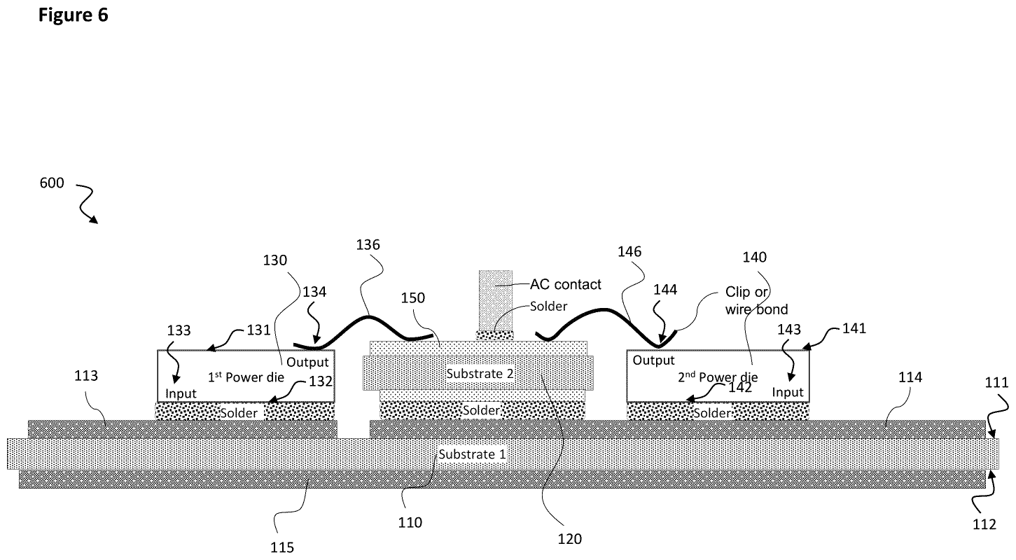

In Embodiment 6, HS and LS face up, vertical current flow, ≥1 die on additional substrate (see FIG. 6):
First and second power semiconductors are vertical devices
First supply voltage area extends at least partly underneath the first power semiconductor facing the input terminal of the first power semiconductor.
Second supply voltage area extends at least partly underneath the second power semiconductor and the AC output of the assembly facing the input terminal of the second power semiconductor.

FIG. 1 shows a schematic cross section of a power converter package 100 according to the first embodiment. The power converter package 100 may be used for converting a first DC voltage and a second DC voltage into a common AC voltage.

The power converter package 100 comprises a first power semiconductor 130 and a second power semiconductor 140 which are configured to generate the common AC voltage based on switching between the first DC voltage and the second DC voltage.

The power converter package 100 comprises a first substrate 110 having a first substrate upper main face 111 and a first substrate lower main face 112 opposing the first substrate upper main face 111. The first substrate 110 comprises a first supply voltage area 113 which is formed to supply the first DC voltage and a second supply voltage area 114 which is formed to supply the second DC voltage. The first supply voltage area 113 and the second supply voltage area 114 are arranged on the first substrate upper main face 111.

The first substrate 110 comprises a base metal area 115 which is arranged on the first substrate lower main face 112. The base metal area 115 is configured to extract dissipated heat from the first power semiconductor 130 and the second power semiconductor 140.

The first power semiconductor 130 comprises a first semiconductor upper main face 131 and a first semiconductor lower main face 132 opposing the first semiconductor upper main face 131.

The first power semiconductor 130 comprises an input terminal 133 and an output terminal 134. The input terminal 133 of the first power semiconductor 130 is connected 135 to the first supply voltage area 113.

The second power semiconductor 140 comprises a second semiconductor upper main face 141 and a second semiconductor lower main face 142 opposing the second semiconductor upper main face 141. The second power semiconductor 140 comprises an input terminal 143 and an output terminal 144. The input terminal 143 of the second power semiconductor 140 is electrically coupled to the second supply voltage area 114.

The power converter package 100 comprises a second substrate 120 having a second substrate upper main face 121 and a second substrate lower main face 122 opposing the second substrate upper main face 121. The second substrate 120 comprises an AC voltage output area 150 formed to provide the AC voltage. The AC voltage output area 150 is placed on top of the second substrate upper main face 121. The AC voltage output area 150 is electrically coupled to the output terminal 134 of the first power semiconductor 130 and the output terminal 144 of the second power semiconductor 140. The second substrate lower main face 122 is placed on top of the second supply voltage area 114.

The second supply voltage area 114 is configured to isolate and shield the AC voltage output area 150 against the base metal area 115 by a placement of the second supply voltage area 114 between the AC voltage output area 150 and the base metal area 115.

Due to the shielding, it can be avoided that the AC output area and the base metal area form a capacitor, which would couple high frequency noise into the base metal area.

The second supply voltage area 114 may be arranged at least partly below the second semiconductor lower main face 142 and may extend underneath the AC voltage output area 150.

This overlap of the second supply voltage area with the AC voltage output area creates the shielding function.

The basic structure of the power converter package 100 described above for the first embodiment is also implemented for the power converter packages 200, 300, 400, 500, 600 described below for the second to sixth embodiments.

Besides the basic structure, described above, the following structural features may be implemented for the first embodiment shown in FIG. 1:

The first power semiconductor 130 and the second power semiconductor 140 can be lateral devices. The input terminal 133 of the first power semiconductor 130 can be arranged on the first semiconductor upper main face 131 and the input terminal 143 of the second power semiconductor 140 can be arranged on the second semiconductor upper main face 141.

In the first embodiment shown in FIG. 1, the first power semiconductor 130 and the second power semiconductor 140 can be face-up mounted on the first substrate 110. The first semiconductor lower main face 132 can face the first supply voltage area 113 and the second semiconductor lower main face 142 can face the second supply voltage area 114.

In the first embodiment shown in FIG. 1, the first supply voltage area 113 may extend at least partly underneath the first semiconductor lower main face 132.

FIG. 2 shows a schematic cross section of a power converter package 200 according to the second embodiment.

The basic structure of the power converter package 100 as described above for the first embodiment is also implemented for the power converter package 200 according to the second embodiment.

Besides the basic structure, described above, the following structural features may be implemented for the second embodiment shown in FIG. 2:

The first power semiconductor 130 and the second power semiconductor 140 can be face-up mounted on the first substrate 110. The first semiconductor lower main face 132 and the second semiconductor lower main face 142 can be facing the second supply voltage area 114.

The second supply voltage area 114 may extend at least partly underneath the first semiconductor lower main face 132, at least partly underneath the second semiconductor lower main face 142 and may extend underneath the AC voltage output area 150.

The first supply voltage area 113 can be placed next to the first power semiconductor 130.

FIG. 3 shows a schematic cross section of a power converter package 300 according to the third embodiment.

The basic structure of the power converter package 100 as described above for the first embodiment is also implemented for the power converter package 300 according to the third embodiment.

Besides the basic structure, described above, the following structural features may be implemented for the third embodiment shown in FIG. 3:

The first power semiconductor 130 and the second power semiconductor 140 can be flip-chip mounted on the second substrate 120. The first semiconductor upper main face 131 and the second semiconductor upper main face 141 can be facing the first substrate upper main face 111.

The second supply voltage area 114 may extend at least partly underneath the first semiconductor upper main face 131, at least partly underneath the second semiconductor upper main face 141 and may extend underneath the AC voltage output area 150.

The first supply voltage area 113 may be placed next to the first power semiconductor 130.

FIG. 4 shows a schematic cross section of a power converter package 400 according to the fourth embodiment.

The basic structure of the power converter package 100 as described above for the first embodiment is also implemented for the power converter package 400 according to the fourth embodiment.

Besides the basic structure, described above, the following structural features may be implemented for the fourth embodiment shown in FIG. 4:

The first power semiconductor 130 can be face-up mounted on the first substrate 110 and the second power semiconductor 140 can be face-up mounted on the second substrate 120. The first semiconductor lower main face 132 can be facing the first supply voltage area 113 and the second substrate lower main face 122 can be facing the second supply voltage area 113.

The first supply voltage area 113 may extend at least partly underneath the first semiconductor lower main face 132.

FIG. 5 shows a schematic cross section of a power converter package 500 according to the fifth embodiment.

The basic structure of the power converter package 100 as described above for the first embodiment is also implemented for the power converter package 500 according to the fifth embodiment.

Besides the basic structure, described above, the following structural features may be implemented for the fifth embodiment shown in FIG. 5:

The first power semiconductor 130 can be face-up mounted on the first substrate 110 and the second power semiconductor 140 can be flip-chip mounted on the second substrate 120. The first semiconductor lower main face 132 can be facing the first supply voltage area 113 and the second semiconductor upper main face 141 can be facing the second substrate upper main face 121.

The second supply voltage area 114 may extend at least partly underneath the second semiconductor upper main face 141 and the AC voltage output area 150.

The first supply voltage area 113 may extend at least partly underneath the first semiconductor lower main face 132.

FIG. 6 shows a schematic cross section of a power converter package 600 according to the sixth embodiment.

The basic structure of the power converter package 100 as described above for the first embodiment is also implemented for the power converter package 600 according to the sixth embodiment.

Besides the basic structure, described above, the following structural features may be implemented for the sixth embodiment shown in FIG. 6:

The first power semiconductor 130 and the second power semiconductor 140 can be vertical devices. The input terminal 133 and the output terminal 134 of the first power semiconductor 130 may be arranged on opposite first semiconductor main faces 132, 131. The input terminal 143 and the output terminal 144 of the second power semiconductor 140 may be arranged on opposite second semiconductor main faces 142, 141.

The first power semiconductor 130 and the second power semiconductor 140 can be face-up mounted on the first substrate 110. The first semiconductor lower main face 132 may be facing the first supply voltage area 113 and the second semiconductor lower main face 142 may be facing the second supply voltage area 114.

The second supply voltage area 114 may extend at least partly underneath the second semiconductor lower main face 142 and may extend at least partly underneath the second substrate lower main face 122.

The first supply voltage area 113 may extend at least partly underneath the first semiconductor lower main face 132.

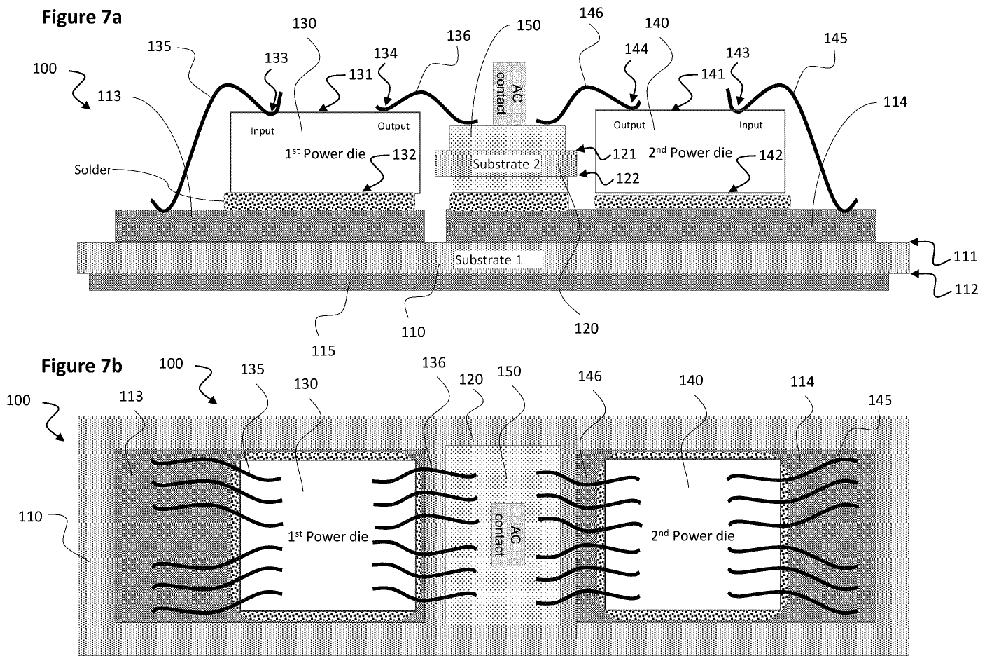

FIG. 7a shows a schematic cross section of the power converter package 100 according to the first embodiment shown in FIG. 1 and FIG. 7b shows a schematic top view of the power converter package 100 according to the first embodiment shown in FIG. 1.

In this exemplary power converter package 100, a first power semiconductor 130 and a second power semiconductor 140 are implemented to realize a single-phase module.

As described above with respect to FIG. 1, HS and LS dies face up and a lateral current flow is implemented. First and second power semiconductors 130, 140 can be lateral devices. First supply voltage area extends at least partly underneath the first power semiconductor facing the substrate side of the first power semiconductor. Second supply voltage area extends at least partly underneath the second power semiconductor and the AC output of the assembly facing the substrate side of the second power semiconductor.

All other embodiments 200, 300, 400, 500, 600 described above can be implemented likewise.

FIG. 8 shows a schematic top view of a multi-phase system with shared supply voltage areas 800 according to a further embodiment.

The multi-phase system with shared supply voltage areas 800 may correspond to any of the power converter packages 100, 200, 300, 400, 500, 600 described above with respect to FIGS. 1 to 6 for which an exemplary number of three first power semiconductors 130 and an exemplary number of three second power semiconductors 140 are implemented.

The AC voltage comprises a plurality of phases, e.g., an exemplary number of three phases as shown in FIG. 8.

The AC voltage output area 150 formed on the second substrate 120 comprises a plurality of isolated phase sections, each phase section associated to a respective phase of the AC voltage. A first AC contact 801 can be placed on a first phase section of the AC voltage output area 150. A second AC contact 802 can be placed on a second phase section of the AC voltage output area 150. A third AC contact 803 can be placed on a third phase section of the AC voltage output area 150.

The AC voltage output area 150 formed on the second substrate 120 comprises a plurality of isolated phase sections, each phase section associated to a respective phase of the AC voltage. A first AC contact 801 can be placed on a first phase section of the AC voltage output area 150. A second AC contact 802 can be placed on a second phase section of the AC voltage output area 150. A third AC contact 803 can be placed on a third phase section of the AC voltage output area 150.

In a further implementation not shown in FIG. 8, a multi-phase system 900 as shown in FIG. 9, can be implemented in a single power converter package.

In such single power converter package, the first substrate 110 comprises a plurality of first supply voltage areas 113, each first supply voltage area 113 associated with a respective phase of the AC voltage, wherein the first supply voltage areas 113 are electrically connected to each other by electrical connectors 911, 912, as exemplarily illustrated in FIG. 9. Each first supply voltage area 113 may be arranged on a respective portion 110a, 110b, 110c of the first substrate 110, as exemplarily shown in FIG. 9.

Similarly, the second substrate 120 comprises a plurality of second supply voltage areas 114, each second supply voltage area 114 associated with a respective phase of the AC voltage, wherein the second supply voltage areas 114 are electrically connected to each other by electrical connectors 913, 914, as exemplarily illustrated in FIG. 9. Each second supply voltage area 114 may be arranged on a respective portion 110a, 110b, 110c of the first substrate 110, as exemplarily shown in FIG. 9.

The first substrate 110 may comprise a plurality of base metal areas 115 (not shown in FIG. 8), each base metal area 115 associated with a respective phase of the AC voltage, wherein the base metal areas 115 form a common base metal area. The base metal areas 115 cannot be seen in the top view of FIG. 9 as they are arranged on the bottom side.

In such a multiphase module in one package, first substrate 110 and second substrate 120 may be shared between multiple phases. That means that 1^{st} supply voltage areas of all phases fuse together, 2^{nd} supply voltage areas of all phases fuse together, and the base metal area 115 of all phases fuse into one common base metal area. The second substrate of each module may be connected mechanically. It may have a lower main face electrical conductor area which connects or not between the multiple phases. The term “fuse” in a wider sense can have the meaning of only “electrically connected to each other (not mechanically)”. Then it can be multiple separate modules which function like a 3-phase system, e.g., as shown in FIG. 9.

FIG. 9 shows a schematic top view of a multi-phase system 900 implemented by multiple of the power converter packages 100 shown in FIG. 1.

The multi-phase system 900 comprises a plurality of power converter packages 100, 200, 300, 400, 500, 600 as described above with respect to FIGS. 1 to 8.

The first supply voltage areas 113 of the first substrates 110 of the plurality of power converter packages 100, 200, 300, 400, 500, 600 are electrically connected to each other by electrical connectors 911, 912 to form a common first supply voltage area for all phases of the multi-phase system.

The second supply voltage areas 114 of the first substrates 110 of the plurality of power converter packages 100, 200, 300, 400, 500, 600 are electrically connected to each other by electrical connectors 913, 914 to form a common second supply voltage area for all phases of the multi-phase system.

The disclosure also presents a method for shielding a power converter package, e.g., a power converter package 100, 200, 300, 400, 500, 600 according to any of the above described embodiments, against common mode conducted emissions. The method comprises: isolating and shielding, by the second supply voltage area of a power converter package 100, 200, 300, 400, 500, 600 described above with respect to FIGS. 1 to 6, the AC voltage output area 150 against the base metal area 115 by a placement of the second supply voltage area 114 between the AC voltage output area 150 and the base metal area 115.

While a particular feature or aspect of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Also, the terms “exemplary”, “for example” and “e.g.” are merely meant as an example, rather than the best or optimal. The terms “coupled” and “connected”, along with derivatives may have been used. It should be understood that these terms may have been used to indicate that two elements cooperate or interact with each other regardless whether they are in direct physical or electrical contact, or they are not in direct contact with each other.

Although specific aspects have been illustrated and described herein, it will be appreciated by those of ordinary skill in the art that a variety of alternate and/or equivalent implementations may be substituted for the specific aspects shown and described without departing from the scope of the disclosure. This application is intended to cover any adaptations or variations of the specific aspects discussed herein.

Although the elements in the following claims are recited in a particular sequence with corresponding labeling, unless the claim recitations otherwise imply a particular sequence for implementing some or all of those elements, those elements are not necessarily intended to be limited to being implemented in that particular sequence.

Many alternatives, modifications, and variations will be apparent to those skilled in the art in light of the above teachings. Of course, those skilled in the art readily recognize that there are numerous applications of the disclosure beyond those described herein. While the disclosure has been described with reference to one or more particular embodiments, those skilled in the art recognize that many changes may be made thereto without departing from the scope of the disclosure. It is therefore to be understood that within the scope of the appended claims and their equivalents, the disclosure may be practiced otherwise than as specifically described herein.

What is claimed is:

1. A power converter package (100, 200, 300, 400, 500, 600) for converting a first DC voltage and a second DC voltage into a common AC voltage, the power converter package (100, 200, 300, 400, 500, 600) comprising:
a first power semiconductor (130) and a second power semiconductor (140) which are configured to generate the common AC voltage based on switching between the first DC voltage and the second DC voltage;
a first substrate (110) having a first substrate upper main face (111) and a first substrate lower main face (112) opposing the first substrate upper main face (111), the first substrate (110) comprising a first supply voltage area (113) being formed to supply the first DC voltage and a second supply voltage area (114) being formed to supply the second DC voltage, the first supply voltage area (113) and the second supply voltage area (114) being arranged on the first substrate upper main face (111);
wherein the first substrate (110) comprises a base metal area (115) being arranged on the first substrate lower main face (112), the base metal area (115) being configured to extract dissipated heat from the first power semiconductor (130) and the second power semiconductor (140);
the first power semiconductor (130) having a first semiconductor upper main face (131) and a first semiconductor lower main face (132) opposing the first semiconductor upper main face (131), the first power semiconductor (130) comprising an input terminal (133) and an output terminal (134), wherein the input terminal (133) of the first power semiconductor (130) is connected (135) to the first supply voltage area (113);
the second power semiconductor (140) having a second semiconductor upper main face (141) and a second semiconductor lower main face (142) opposing the second semiconductor upper main face (141), the second power semiconductor (140) comprising an input terminal (143) and an output terminal (144), wherein the input terminal (143) of the second power semiconductor (140) is electrically coupled to the second supply voltage area (114); and
a second substrate (120) having a second substrate upper main face (121) and a second substrate lower main face (122) opposing the second substrate upper main face (121), the second substrate (120) comprising an AC voltage output area (150) formed to provide the AC voltage, the AC voltage output area (150) being placed on top of the second substrate upper main face (121), wherein the AC voltage output area (150) is electrically coupled to the output terminal (134) of the first power semiconductor (130) and the output terminal (144) of the second power semiconductor (140), wherein the second substrate lower main face (122) is placed on top of the second supply voltage area (114),
wherein the second supply voltage area (114) is configured to isolate and shield the AC voltage output area (150) against the base metal area (115) by a placement of the second supply voltage area (114) between the AC voltage output area (150) and the base metal area (115).

2. The power converter package (100) of claim 1,
wherein the second supply voltage area (114) is arranged at least partly below the second semiconductor lower main face (142) and extends underneath the AC voltage output area (150).

3. The power converter package (100) of claim 1,
wherein the first power semiconductor (130) and the second power semiconductor (140) are lateral devices, the input terminal (133) of the first power semiconductor (130) being arranged on the first semiconductor upper main face (131) and the input terminal (143) of the second power semiconductor (140) being arranged on the second semiconductor upper main face (141).

4. The power converter package (100) of claim 1,
wherein the first power semiconductor (130) and the second power semiconductor (140) are face-up mounted on the first substrate (110), the first semiconductor lower main face (132) facing the first supply voltage area (113) and the second semiconductor lower main face (142) facing the second supply voltage area (114).

5. The power converter package (100) of claim 1,
wherein the first supply voltage area (113) extends at least partly underneath the first semiconductor lower main face (132).

6. The power converter package (200) of claim 1,
wherein the first power semiconductor (130) and the second power semiconductor (140) are face-up mounted on the first substrate (110), the first semiconductor lower main face (132) and the second semiconductor lower main face (142) facing the second supply voltage area (114).

7. The power converter package (200) of claim 6,
wherein the second supply voltage area (114) extends at least partly underneath the first semiconductor lower main face (132), at least partly underneath the second semiconductor lower main face (142) and extends underneath the AC voltage output area (150).

8. The power converter package (200) of claim 6,
wherein the first supply voltage area (113) is placed next to the first power semiconductor (130).

9. The power converter package (300) of claim 1,
wherein the first power semiconductor (130) and the second power semiconductor (140) are flip-chip mounted on the second substrate (120), the first semiconductor upper main face (131) and the second semiconductor upper main face (141) facing the first substrate upper main face (111).

10. The power converter package (300) of claim 9,
wherein the second supply voltage area (114) extends at least partly underneath the first semiconductor upper main face (131), at least partly underneath the second semiconductor upper main face (141) and extends underneath the AC voltage output area (150).

11. The power converter package (300) of claim 9,
wherein the first supply voltage area (113) is placed next to the first power semiconductor (130).

12. The power converter package (400) of claim 1,
wherein the first power semiconductor (130) is face-up mounted on the first substrate (110) and the second power semiconductor (140) is face-up mounted on the second substrate (120), the first semiconductor lower main face (132) facing the first supply voltage area (113) and the second substrate lower main face (122) facing the second supply voltage area (113).

13. The power converter package (400) of claim 1,
wherein the first supply voltage area (113) extends at least partly underneath the first semiconductor lower main face (132).

14. The power converter package (500) of claim 1,
wherein the first power semiconductor (130) is face-up mounted on the first substrate (110) and the second power semiconductor (140) is flip-chip mounted on the second substrate (120), the first semiconductor lower main face (132) facing the first supply voltage area (113) and the second semiconductor upper main face (141) facing the second substrate upper main face (121).

15. The power converter package (500) of claim 14,
wherein the second supply voltage area (114) extends at least partly underneath the second semiconductor upper main face (141) and the AC voltage output area (150).

16. The power converter package (500) of claim 14,
wherein the first supply voltage area (113) extends at least partly underneath the first semiconductor lower main face (132).

17. The power converter package (600) of claim 1,
wherein the first power semiconductor (130) and the second power semiconductor (140) are vertical devices; the input terminal (133) and the output terminal (134) of the first power semiconductor (130) being arranged on opposite first semiconductor main faces (132, 131); and the input terminal (143) and the output terminal (144) of the second power semiconductor (140) being arranged on opposite second semiconductor main faces (142, 141).

18. The power converter package (600) of any of claim 1,
wherein the first power semiconductor (130) and the second power semiconductor (140) are face-up mounted on the first substrate (110), the first semiconductor lower main face (132) facing the first supply voltage area (113) and the second semiconductor lower main face (142) facing the second supply voltage area (114).

19. The power converter package (100, 200, 300, 400, 500, 600) of claim 1,
wherein the first power semiconductor (130) and the second power semiconductor (140) are electrically connected to a half-bridge topology.

20. A multi-phase system, comprising:
a plurality of power converter packages (100, 200, 300, 400, 500, 600), the power converter package (100, 200, 300, 400, 500, 600) comprising:
a first power semiconductor (130) and a second power semiconductor (140) which are configured to generate the common AC voltage based on switching between the first DC voltage and the second DC voltage; wherein the first power semiconductor (130) and the second power semiconductor (140) are electrically connected to a half-bridge topology;
a first substrate (110) having a first substrate upper main face (111) and a first substrate lower main face (112) opposing the first substrate upper main face (111), the first substrate (110) comprising a first supply voltage area (113) being formed to supply the first DC voltage and a second supply voltage area (114) being formed to supply the second DC voltage, the first supply voltage area (113) and the second supply voltage area (114) being arranged on the first substrate upper main face (111);
wherein the first substrate (110) comprises a base metal area (115) being arranged on the first substrate lower main face (112), the base metal area (115) being configured to extract dissipated heat from the first power semiconductor (130) and the second power semiconductor (140);
the first power semiconductor (130) having a first semiconductor upper main face (131) and a first semiconductor lower main face (132) opposing the first semiconductor upper main face (131), the first power semiconductor (130) comprising an input terminal (133) and an output terminal (134), wherein the input terminal (133) of the first power semiconductor (130) is connected (135) to the first supply voltage area (113);
the second power semiconductor (140) having a second semiconductor upper main face (141) and a second semiconductor lower main face (142) opposing the second semiconductor upper main face (141), the second power semiconductor (140) comprising an input terminal (143) and an output terminal (144), wherein the input terminal (143) of the second power semiconductor (140) is electrically coupled to the second supply voltage area (114); and
a second substrate (120) having a second substrate upper main face (121) and a second substrate lower main face (122) opposing the second substrate upper main face (121), the second substrate (120) comprising an AC voltage output area (150) formed to provide the AC voltage, the AC voltage output area (150) being placed on top of the second substrate upper main face (121), wherein the AC voltage output area (150) is electrically coupled to the output terminal (134) of the first power semiconductor (130) and the output terminal (144) of the second power semiconductor (140), wherein the second substrate lower main face (122) is placed on top of the second supply voltage area (114),
wherein the second supply voltage area (114) is configured to isolate and shield the AC voltage output area (150) against the base metal area (115) by a placement of the second supply voltage area (114) between the AC voltage output area (150) and the base metal area (115);
wherein the first supply voltage areas (113) of the first substrates (110) of the plurality of power converter packages (100, 200, 300, 400, 500, 600) are electrically connected to each other to form a common first supply voltage area for all phases of the multi-phase system; and
wherein the second supply voltage areas (114) of the first substrates (110) of the plurality of power converter packages (100, 200, 300, 400, 500, 600) are electrically connected to each other to form a common second supply voltage area for all phases of the multi-phase system.
